(19) United States
(12) Patent Application Publication
(10) Pub. No.: US 2015/0280683 A1
(43) Pub. Date: Oct. 1, 2015

(54) PHASE SHIFT CIRCUIT, OSCILLATOR, ELECTRONIC APPARATUS, AND MOVING OBJECT

(71) Applicant: Seiko Epson Corporation, Tokyo (JP)

(72) Inventor: Masataka NOMURA, Minowa (JP)

(21) Appl. No.: 14/674,003

(22) Filed: Mar. 31, 2015

(30) Foreign Application Priority Data
Apr. 1, 2014 (JP) 2014-075372

(51) Int. Cl. H03H 7/20; H03B 5/02

(52) U.S. Cl. CPC H03H 7/20; H03B 5/02

(57) ABSTRACT

A phase shift circuit includes a first capacitance circuit, a second capacitance circuit, an inductance circuit, and a third capacitance circuit having a first terminal electrically connected to one end (first terminal) of the inductance circuit, a second terminal electrically connected to the other end (second terminal) of the inductance circuit, and a third terminal, and one end (first terminal) of the first capacitance circuit, one end (first terminal) of the second capacitance circuit, the first terminal of the third capacitance circuit, and the one end (first terminal) of the inductance circuit are electrically connected to one another.

### BACKGROUND

1. Technical Field

The present invention relates to a phase shift circuit, an oscillator, an electronic apparatus, and a moving object.

2. Related Art

A variety of phase shift circuits that shift the phase of a signal have been developed. One application of such a phase shift circuit is an oscillator using a phase shift circuit (phase shifter).

JP-UM-A-4-86314 discloses an SAW (surface acoustic wave) oscillator including a phase shifter using two capacitors connected in series to an input terminal of an SAW resonator and one inductor connected in parallel to the two capacitors and located between a ground and a connection point where the two capacitors are connected to each other. In the phase shifter, when the amount of phase shift in the SAW device changes in response to a change in ambient temperature, the capacitance of each of the capacitors changes in such a way that the change cancels the change in the phase shift in the SAW device so that the phase changes and the oscillation frequency remains unchanged.

In the oscillator described in JP-UM-A-4-86314, when the resonator is changed to another in order to change the oscillation frequency, the amount of phase shift in the resonator also changes in some cases. In such cases, the inductance of a coil provided in the phase shifter needs to be changed in order to change the amount of phase shift provided by the phase shifter. It has, however, not been easy to change the inductance of the coil by using an external control signal. Instead, as a method for changing the inductance of the coil, it is conceivable to use a method for replacing the coil with a coil having a different inductance value. In this method, however, the step of replacing the coil is added, possibly resulting in cumbersome work.

### SUMMARY

An advantage of some aspect of the invention is to provide a phase shift circuit, an oscillator, an electronic apparatus, and a moving object that allow the amount of phase shift to be readily changed.

The invention can be implemented as the following aspects or application examples:

### Application Example 1

A phase shift circuit according to this application example includes a first capacitance circuit, a second capacitance circuit, an inductance circuit, and a third capacitance circuit having a first terminal electrically connected to one end of the inductance circuit, a second terminal electrically connected to the other end of the inductance circuit, and a third terminal to which a signal that controls capacitance is inputted, and one end of the first capacitance circuit, one end of the second capacitance circuit, the first terminal of the third capacitance circuit, and the one end of the inductance circuit are electrically connected to one another.

According to this application example, in which the third capacitance circuit controls the capacitance connected in parallel to the inductance circuit, the amount of phase shift can be changed. A phase shift circuit that allows the amount of phase shift to be readily changed can therefore be provided.

### Application Example 2

In the phase shift circuit described above, the third capacitance circuit may include a switch element having the third terminal and a capacitive element, and the switch element and the capacitive element may be connected in series to each other between the first terminal and the second terminal.

In the configured described above, the capacitance connected in parallel to the inductance circuit can be readily switched between zero and a predetermined value. The phase shift circuit achieved in this application example therefore allows the amount of phase shift to be readily changed.

### Application Example 3

In the phase shift circuit described above, at least one of the first capacitance circuit, the second capacitance circuit, and the third capacitance circuit may have a variable capacitive element.

In the configuration described above, the capacitance of at least one of the first capacitance circuit, the second capacitance circuit, and the third capacitance circuit can be readily changed. The phase shift circuit achieved in this application example therefore allows the amount of phase shift to be readily changed.

### Application Example 4

In the phase shift circuit described above, the third capacitance circuit may have a variable capacitance circuit in which two variable capacitive elements are connected in series to each other between the first terminal and the second terminal, and the third terminal may be a connection point where the two variable capacitive elements are connected to each other.

In the configuration described above, the capacitance connected in parallel to the inductance circuit can be readily changed. The phase shift circuit achieved in this application example therefore allows the amount of phase shift to be readily changed.

### Application Example 5

In the phase shift circuit described above, each of the first capacitance circuit and the second capacitance circuit may have a variable capacitive element, a first voltage may be applied to the one end of the first capacitance circuit, the one end of the second capacitance circuit, and the first terminal of the third capacitance circuit, a second voltage may be applied in the form of a DC voltage to the other end of the first capacitance circuit, a third voltage may be applied in the form of a DC voltage to the other end of the second capacitance circuit, and a fourth voltage may be applied in the form of a DC voltage to the third terminal of the third capacitance circuit.

In the configuration described above, the capacitance of each of the first capacitance circuit, the second capacitance circuit, and the third capacitance circuit can be readily changed. The phase shift circuit achieved in this application example therefore allows the amount of phase shift to be readily changed.

### Application Example 6

In the phase shift circuit described above, the second voltage, the third voltage, and the fourth voltage may be the same voltage.

In the configuration described above, a single control signal can be used to readily change the capacitance of each of the first capacitance circuit, the second capacitance circuit, and the third capacitance circuit.

### Application Example 7

The phase shift circuit described above may further include a fourth capacitance circuit and a fifth capacitance circuit, and one end of the fourth capacitance circuit, one end of the fifth capacitance circuit, the second terminal of the third capacitance circuit, and the other end of the inductance circuit may be electrically connected to one another.

The configuration described above provides a phase shift circuit having a differential input and a differential output.

### Application Example 8

In the phase shift circuit described above, the third capacitance circuit may include a switch element having the third terminal and a capacitive element, and the switch element and the capacitive element may be connected in series to each other between the first terminal and the second terminal.

In the configured described above, the capacitance connected in parallel to the inductance circuit can be switched between zero and a predetermined value. The phase shift circuit achieved in this application example therefore allows the amount of phase shift to be readily changed.

### Application Example 9

In the phase shift circuit described above, at least one of the first capacitance circuit, the second capacitance circuit, the third capacitance circuit, the fourth capacitance circuit, and the fifth capacitance circuit may have a variable capacitive element.

In the configuration described above, the capacitance of at least one of the first capacitance circuit, the second capacitance circuit, the third capacitance circuit, the fourth capacitance circuit, and the fifth capacitance circuit can be readily changed. The phase shift circuit achieved in this application example therefore allows the amount of phase shift to be readily changed.

### Application Example 10

In the phase shift circuit described above, the third capacitance circuit may have a variable capacitance circuit in which two variable capacitive elements are connected in series to each other between the first terminal and the second terminal, and the third terminal may be a connection point where the two variable capacitive elements are connected to each other.

In the configuration described above, the capacitance connected in parallel to the inductance circuit can be readily changed. The phase shift circuit achieved in this application example therefore allows the amount of phase shift to be readily changed.

### Application Example 11

In the phase shift circuit described above, each of the first capacitance circuit, the second capacitance circuit, the fourth capacitance circuit, and the fifth capacitance circuit may have a variable capacitive element, a first voltage may be applied in the form of a DC voltage to the one end of the first capacitance circuit, the one end of the second capacitance circuit, and the first terminal of the third capacitance circuit, a second voltage may be applied in the form of a DC voltage to the other end of the first capacitance circuit, a third voltage may be applied in the form of a DC voltage to the other end of the second capacitance circuit, a fourth voltage may be applied in the form of a DC voltage to the third terminal of the third capacitance circuit, a fifth voltage may be applied in the form of a DC voltage to the one end of the fourth capacitance circuit, the one end of the fifth capacitance circuit, and the second terminal of the third capacitance circuit, a sixth voltage may be applied in the form of a DC voltage to the other end of the fourth capacitance circuit, and a seventh voltage may be applied in the form of a DC voltage to the other end of the fifth capacitance circuit.

In the configuration described above, the capacitance of each of the first capacitance circuit, the second capacitance circuit, the third capacitance circuit, the fourth capacitance circuit, and the fifth capacitance circuit can be readily changed. The phase shift circuit achieved in this application example therefore allows the amount of phase shift to be readily changed.

### Application Example 12

In the phase shift circuit described above, the second voltage, the third voltage, the fourth voltage, the sixth voltage, and the seventh voltage may be the same voltage.

In the configuration described above, a single control signal can be used to readily change the capacitance of each of the first capacitance circuit, the second capacitance circuit, the third capacitance circuit, the fourth capacitance circuit, and the fifth capacitance circuit.

### Application Example 13

An oscillator according to this application example includes any of the phase shift circuits described above.

The oscillator described above, which includes the phase shift circuit that allows the amount of phase shift to be readily changed, allows the oscillation frequency to be readily adjusted and controlled.

### Application Example 14

An electronic apparatus according to this application example includes any of the phase shift circuits described above.

### Application Example 15

A moving object according to this application example includes any of the phase shift circuits described above.

The electronic apparatus and the moving object described above, each of which includes the phase shift circuit that allows the amount of phase shift to be readily changed, can readily change its operation.

### BRIEF DESCRIPTION OF THE DRAWINGS

The invention will be described with reference to the accompanying drawings, wherein like numbers reference like elements.

FIG. 1 is a circuit diagram of a phase shift circuit according to a first embodiment.

FIG. 2 is a circuit diagram of a phase shift circuit according to a second embodiment.

FIG. 3 is a circuit diagram of a phase shift circuit according to a third embodiment.

FIG. 4 is a circuit diagram of a phase shift circuit according to a fourth embodiment.

FIG. 5A shows graphs representing simulation results showing the relationship between the frequency and the phase associated with the phase shift circuit according to the fourth embodiment, and FIG. 5B shows graphs representing simulation results showing the relationship between the frequency and insertion loss associated with the phase shift circuit according to the fourth embodiment.

FIG. 6 is a circuit diagram of an oscillator using the phase shift circuit according to the fourth embodiment.

FIG. 7 is a functional block diagram of an electronic apparatus according to the present embodiment.

FIG. 8A shows an example of the exterior appearance of a smartphone, which is an example of the electronic apparatus, and FIG. 8B shows a wristwatch-type mobile apparatus as an example of the electronic apparatus.

FIG. 9 shows an example of a moving object according to the present embodiment (top view).

### DESCRIPTION OF EXEMPLARY EMBODIMENTS

Preferable embodiments of the invention will be described below in detail with reference to the drawings. The drawings used below are presented for convenience of description. It is not intended that the embodiments, which will be described below, unduly limit the contents of the invention set forth in the appended claims. Further, all configurations described below are not necessarily essential configuration requirements of the invention.

### 1. Phase shift circuit

### 1-1. First embodiment

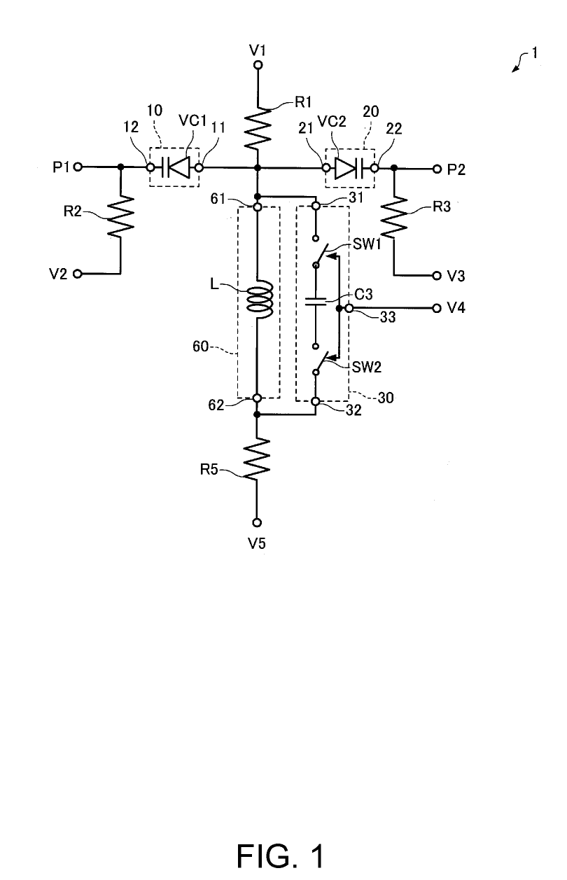

FIG. 1 is a circuit diagram of a phase shift circuit 1 according to a first embodiment. At least part of the phase shift circuit 1 may be configured as a semiconductor device.

The phase shift circuit 1 according to the present embodiment includes a first capacitance circuit 10, a second capacitance circuit 20, an inductance circuit 60, and a third capacitance circuit 30, and the third capacitance circuit 30 has a first terminal 31, which is electrically connected to one end (first terminal 61) of the inductance circuit 60, a second terminal 32, which is electrically connected to the other end (second terminal 62) of the inductance circuit 60, and a third terminal 33, to which a signal that controls capacitance is inputted. One end (first terminal 11) of the first capacitance circuit 10, one end (first terminal 21) of the second capacitance circuit 20, the first terminal 31 of the third capacitance circuit 30, and the one end (first terminal 61) of the inductance circuit 60 are electrically connected to one another.

The first capacitance circuit 10 has a first terminal 11 and a second terminal 12. The first capacitance circuit has a capacitive element (capacitor, varicap, or MOS capacitor, for example) between the first terminal 11 and the second terminal 12. The first capacitance circuit 10 may have a plurality of capacitive elements electrically connected to each other by using at least one of a series connection method and a parallel connection method. In the example shown in FIG. 1, the first capacitance circuit 10 has a variable capacitive element VC1 between the first terminal 11 and the second terminal 12, and the variable capacitive element VC1 is formed of a varicap having an anode facing the first terminal 11 and a cathode facing the second terminal 12. The second terminal of the first capacitance circuit 10 is electrically connected to a terminal P1.

The second capacitance circuit 20 has a first terminal 21 and a second terminal 22. The second capacitance circuit 20 has a capacitive element (capacitor, varicap, or MOS capacitor, for example) between the first terminal 21 and the second terminal 22. The second capacitance circuit 20 may have a plurality of capacitive elements electrically connected to each other by using at least one of a series connection method and a parallel connection method. In the example shown in FIG. 1, the second capacitance circuit 20 has a variable capacitive element VC2 between the first terminal 21 and the second terminal 22, and the variable capacitive element VC2 is formed of a varicap having an anode facing the first terminal 21 and a cathode facing the second terminal 22. The second terminal of the second capacitance circuit 20 is electrically connected to a terminal P2.

The inductance circuit 60 has a first terminal 61 and a second terminal 62. The inductance circuit 60 has an inductive element (coil, for example) between the first terminal 61 and the second terminal 62. The inductance circuit 60 may have a plurality of inductive elements electrically connected to each other by using at least one of a series connection method and a parallel connection method. In the example shown in FIG. 1, the inductance circuit 60 has an inductive element L between the first terminal 61 and the second terminal 62.

The third capacitance circuit 30 has the first terminal 31, the second terminal 32, and the third terminal 33. The third capacitance circuit 30 has a capacitive element (capacitor, varicap, or MOS capacitor, for example) between the first terminal 31 and the second terminal 32. The third capacitance circuit 30 may have a plurality of capacitive elements electrically connected to each other by using at least one of a series connection method and a parallel connection method. In the example shown in FIG. 1, the third capacitance circuit 30 has the following components between the first terminal 31 and the second terminal 32: a switch element SW1; a capacitive element C3; and a switch element SW2, which are connected to each other in series sequentially from the side where the first terminal 31 is present toward the side where the second terminal 32 is present. The capacitive element C3 may be a fixed capacitive element or a variable capacitive element.

The third terminal 33 of the third capacitance circuit 30 receives, as an input, a signal that controls the capacitance between the first terminal 31 and the second terminal 32. In the example shown in FIG. 1, the third terminal 33 is electrically connected to control terminals of the switch element SW1 and the switch element SW2. Further, a fourth voltage V4 is applied to the third terminal 33. In the third capacitance circuit 30, the capacitance between the first terminal 31 and the second terminal 33 changes when the connection to the switch element SW1 is switched to the connection to the switch element SW2 and vice versa.

The first terminal 11 of the first capacitance circuit 10, the first terminal 21 of the second capacitance circuit 20, the first terminal 31 of the third capacitance circuit 30, and the first terminal 61 of the inductance circuit 60 are electrically connected to one another. In the example shown in FIG. 1, a first voltage V1 is applied in the form of a DC voltage via a resistor R1 to a common connection point where the terminals described above are connected to one another. Further, in the example shown in FIG. 1, a fifth voltage V5 is applied in the form of a DC voltage via a resistor R5 to a common connection point where the second terminal 62 of the inductance circuit 60 and the second terminal 32 of the third capacitance circuit 30 are connected to each other. The first voltage V1 and the fifth voltage V5 may, for example, be the same voltage, such as a ground potential.

In the present embodiment, the phase shift circuit 1 is a phase shift circuit having the terminal P1 as an input terminal and the terminal P2 as an output terminal. The phase shift circuit 1 may instead be a phase shift circuit having the terminal P1 as an output terminal and the terminal P2 as an input terminal.

In the phase shift circuit 1 according to the present embodiment, the third capacitance circuit 30 can change the amount of phase shift by controlling the capacitance connected in parallel to the inductance circuit 60. Since the third capacitance circuit 30 can readily change the capacitance by using an external signal as compared with a case where the inductance of the inductance circuit 60 is changed by using an external signal and a case where the inductance of the inductance circuit 60 is changed by replacing the inductive element L of the inductance circuit 60, the amount of phase shift can be changed in accordance with a result of combination of the impedance of the inductance L and the impedance of the third capacitance circuit 30. The phase shift circuit 1 achieved in the present embodiment therefore allows the amount of phase shift to be readily changed.

In the phase shift circuit 1 according to the present embodiment, the third capacitance circuit 30 may include the switch elements having the third terminal 33 (switch element SW1 and switch element SW2) and the capacitive element C3, and the switch elements (switch element SW1 and switch element SW2) and the capacitive element C3 may be connected in series to each other between the first terminal 31 and the second terminal 32, as shown in FIG. 1. The thus configured third capacitance circuit 30 can readily switch the capacitance connected in parallel to the inductance circuit 60 between zero and a predetermined value. The phase shift circuit 1 achieved in the present embodiment therefore allows the amount of phase shift to be readily changed.

In the phase shift circuit 1 according to the present embodiment, at least one of the first capacitance circuit 10, the second capacitance circuit 20, and the third capacitance circuit 30 may have a variable capacitive element. In the example shown in FIG. 1, the first capacitance circuit 10 has the variable capacitive element VC1, which is a varicap, and the second capacitance circuit 20 has the variable capacitive element VC2, which is a varicap.

In the example shown in FIG. 1, a second voltage V2 is applied in the form of a DC voltage to the second terminal 12 of the first capacitance circuit 10 via a resistor R2. The capacitance of the variable capacitive element VC1 can therefore be controlled by controlling the difference in potential between the first voltage V1 and the second voltage V2.

In the example shown in FIG. 1, a third voltage V3 is applied in the form of a DC voltage to the second terminal 22 of the second capacitance circuit 20 via a resistor R3. The capacitance of the variable capacitive element VC2 can therefore be controlled by controlling the difference in potential between the first voltage V1 and the third voltage V3.

As described above, the phase shift circuit 1 according to the present embodiment can readily change the capacitance of at least one of the first capacitance circuit 10, the second capacitance circuit 20, and the third capacitance circuit 30. The phase shift circuit 1 achieved in the present embodiment therefore allows the amount of phase shift to be readily changed.

### 1-2. Second Embodiment

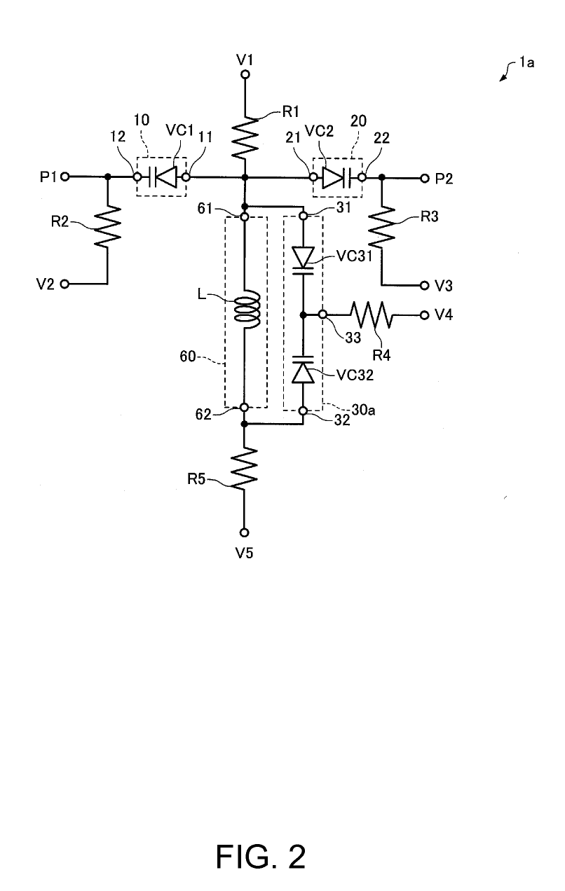

FIG. 2 is a circuit diagram of a phase shift circuit la according to a second embodiment. The same configurations as those in the phase shift circuit 1 according to the first embodiment have the same reference characters and will not be described in detail.

In the phase shift circuit la according to the present embodiment, a third capacitance circuit 30a has a variable capacitance circuit in which two variable capacitive elements (variable capacitive element VC31 and variable capacitive element VC32) are connected in series to each other between the first terminal 31 and the second terminal 32, and the third terminal 33 is a connection point where the two variable capacitive elements (variable capacitive element VC31 and variable capacitive element VC32) are connected to each other. In the example shown in FIG. 2, the fourth voltage V4 is applied in the form of a DC voltage to the third terminal 33 via a resistor R4.

In the example shown in FIG. 2, the variable capacitive element VC31 is formed of a varicap having an anode facing the first terminal 31 and a cathode facing the third terminal 33. The capacitance of the variable capacitive element VC31 can therefore be controlled by controlling the difference in potential between the first voltage V1 and the fourth voltage V4.

In the example shown in FIG. 2, the variable capacitive element VC32 is formed of a varicap having an anode facing the second terminal 32 and a cathode facing the third terminal 33. The capacitance of the variable capacitive element VC32 can therefore be controlled by controlling the difference in potential between the fifth voltage V5 and the fourth voltage V4.

The phase shift circuit la according to the present embodiment can readily change the capacitance connected in parallel to the inductance circuit 60. The phase shift circuit la achieved in the present embodiment therefore allows the amount of phase shift to be readily changed.

As shown in FIG. 2, in the phase shift circuit la according to the present embodiment, the first capacitance circuit 10 and the second capacitance circuit 20 may have the variable capacitive elements (variable capacitive element VC1 and variable capacitive element VC2), and the first voltage V1 may be applied to the first terminal 11 of the first capacitance circuit 10, the first terminal 21 of the second capacitance circuit 20, and the first terminal 31 of the third capacitance circuit 30a, the second voltage V2 may be applied in the form of a DC voltage to the second terminal 12 of the first capacitance circuit 10, the third voltage V3 may be applied in the form of a DC voltage to the second terminal 22 of the second capacitance circuit 20, and the fourth voltage V4 may be applied in the form of a DC voltage to the third terminal 33 of the third capacitance circuit 30a. The capacitance of each of the first capacitance circuit 10, the second capacitance circuit 20, and the third capacitance circuit 30a can therefore be readily changed. The phase shift circuit la achieved in the present embodiment therefore allows the amount of phase shift to be readily changed.

In the phase shift circuit la according to the present embodiment, the second voltage V2, the third voltage V3, and the fourth voltage V4 may be the same voltage. In this case, a single control signal (voltage signal) can be used to readily change the capacitance of each of the first capacitance circuit 10, the second capacitance circuit 20, and the third capacitance circuit 30a.

The phase shift circuit la according to the present embodiment also provides the same advantageous effect as that provided by the phase shift circuit 1 according to the first embodiment from the same reason.

### 1-3. Third Embodiment

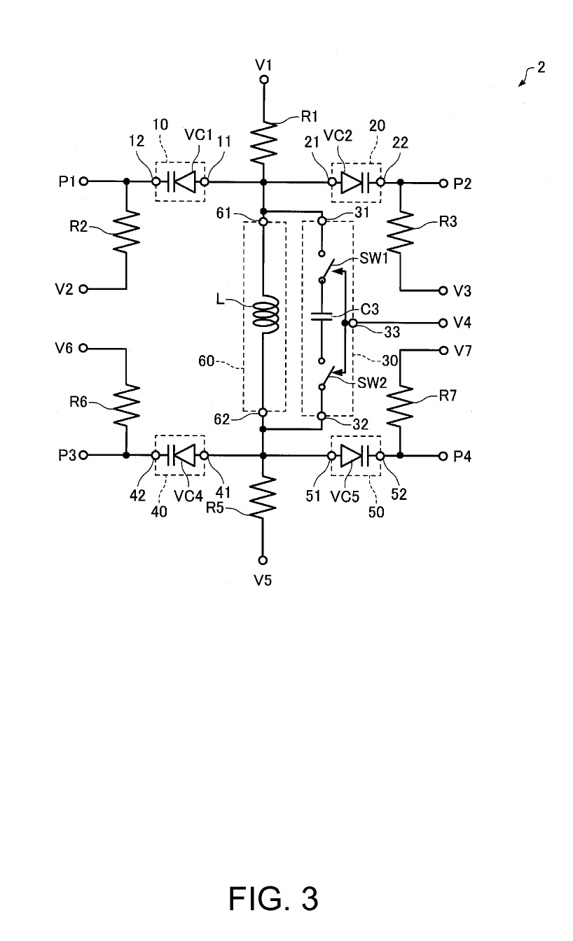

FIG. 3 is a circuit diagram of a phase shift circuit 2 according to a third embodiment. The same configurations as those in the phase shift circuit 1 according to the first embodiment have the same reference characters and will not be described in detail.

The phase shift circuit 2 according to the present embodiment further includes a fourth capacitance circuit 40 and a fifth capacitance circuit 50, and one end (first terminal 41) of the fourth capacitance circuit 40, one end (first terminal 51) of the fifth capacitance circuit 50, the second terminal 32 of the third capacitance circuit 30, and the second terminal 62 of the inductance circuit 60 are electrically connected to one another.

The fourth capacitance circuit 40 has a first terminal 41 and a second terminal 42. The fourth capacitance circuit 40 has a capacitive element (capacitor, varicap, or MOS capacitor, for example) between the first terminal 41 and the second terminal 42. The fourth capacitance circuit 40 may have a plurality of capacitive elements electrically connected to each other by using at least one of a series connection method and a parallel connection method. In the example shown in FIG. 3, the fourth capacitance circuit 40 has a variable capacitive element VC4 between the first terminal 41 and the second terminal 42, and the variable capacitive element VC4 is formed of a varicap having an anode facing the first terminal 41 and a cathode facing the second terminal 42. The second terminal of the fourth capacitance circuit 40 is electrically connected to a terminal P3.

The fifth capacitance circuit 50 has a first terminal 51 and a second terminal 52. The fifth capacitance circuit has a capacitive element (capacitor, varicap, or MOS capacitor, for example) between the first terminal 51 and the second terminal 52. The fifth capacitance circuit 50 may have a plurality of capacitive elements electrically connected to each other by using at least one of a series connection method and a parallel connection method. In the example shown in FIG. 3, the fifth capacitance circuit 50 has a variable capacitive element VC5 between the first terminal 51 and the second terminal 52, and the variable capacitive element VC5 is formed of a varicap having an anode facing the first terminal 51 and a cathode facing the second terminal 52. The second terminal of the fifth capacitance circuit 50 is electrically connected to a terminal P4.

The first terminal 41 of the fourth capacitance circuit 40, the first terminal 51 of the fifth capacitance circuit 50, the second terminal 32 of the third capacitance circuit 30, and the second terminal 62 of the inductance circuit 60 are electrically connected to one another. In the example shown in FIG. 3, the fifth voltage V5 is applied in the form of a DC voltage via a resistor R5 to a common connection points where the terminals described above are connected to one another.

In the present embodiment, the phase shift circuit 2 is a phase shift circuit having the terminals P1 and P3 as input terminals and the terminals P2 and P4 as output terminals. The phase shift circuit 2 may instead be a phase shift circuit having the terminals P1 and P3 as output terminals and the terminals P2 and P4 as input terminals.

The phase shift circuit 2 according to the present embodiment can form a phase shift circuit having a differential input and a differential output.

As shown in FIG. 3, in the phase shift circuit 2 according to the present embodiment, the third capacitance circuit 30 may include the switch elements (switch element SW1 and switch element SW2) having the third terminal 33 and the capacitive element C3, and the switch elements (switch element SW1 and switch element SW2) and the capacitive element C3 may be connected in series to each other between the first terminal 31 and the second terminal 32. The thus configured third capacitance circuit 30 can readily switch the capacitance connected in parallel to the inductance circuit 60 between zero and a predetermined value. The phase shift circuit 2 achieved in the present embodiment therefore allows the amount of phase shift to be readily changed.

In the phase shift circuit 2 according to the present embodiment, at least one of the first capacitance circuit 10, the second capacitance circuit 20, the third capacitance circuit 30, the fourth capacitance circuit 40, and the fifth capacitance circuit 50 may have a variable capacitive element. In the example shown in FIG. 3, the first capacitance circuit 10 has the variable capacitive element VC1, which is a varicap, the second capacitance circuit 20 has the variable capacitive element VC2, which is a varicap, the fourth capacitance circuit 40 has the variable capacitive element VC4, which is a varicap, and the fifth capacitance circuit 50 has the variable capacitive element VC5, which is a varicap. The first capacitance circuit 10 and the second capacitance circuit 20 have been already described in the first embodiment.

In the example shown in FIG. 3, a sixth voltage V6 is applied in the form of a DC voltage to the second terminal 42 of the fourth capacitance circuit 40 via a resistor R6. The capacitance of the variable capacitive element VC4 can therefore be controlled by controlling the difference in potential between the fifth voltage V5 and the sixth voltage V6.

In the example shown in FIG. 3, a seventh voltage V7 is applied in the form of a DC voltage to the second terminal 52 of the fifth capacitance circuit 50 via a resistor R7. The capacitance of the variable capacitive element VC5 can therefore be controlled by controlling the difference in potential between the fifth voltage V5 and the seventh voltage V7.

The phase shift circuit 2 according to the present embodiment can readily change the capacitance of at least one of the first capacitance circuit 10, the second capacitance circuit 20, the third capacitance circuit 30, the fourth capacitance circuit 40, and the fifth capacitance circuit 50. The phase shift circuit 2 achieved in the present embodiment therefore allows the amount of phase shift to be readily changed.

The phase shift circuit 2 according to the present embodiment also provides the same advantageous effect as that provided by the phase shift circuit 1 according to the first embodiment from the same reason.

### 1-4. Fourth Embodiment

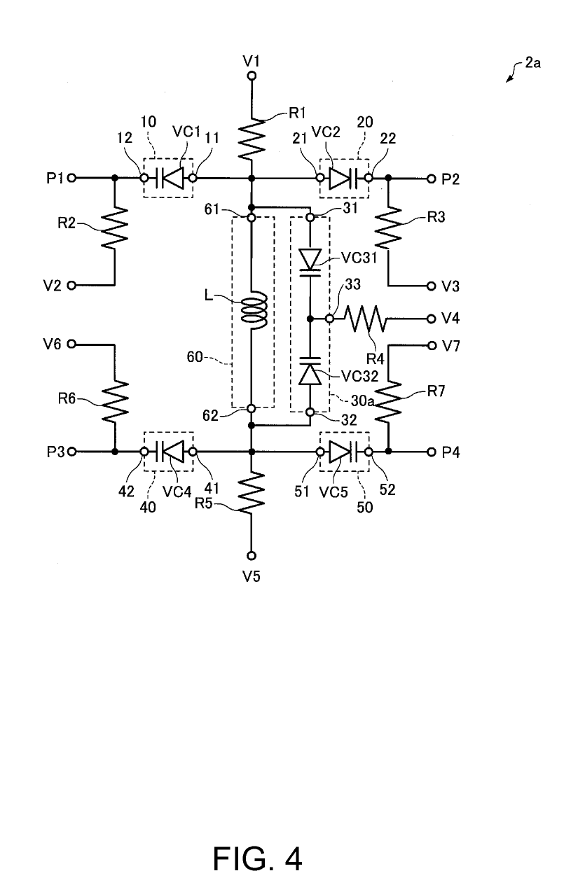

FIG. 4 is a circuit diagram of a phase shift circuit 2a according to a fourth embodiment. The same configurations as those in the phase shift circuit 1 according to the first embodiment, the phase shift circuit la according to the second embodiment, and the phase shift circuit 2 according to the third embodiment have the same reference characters and will not be described in detail.

In the phase shift circuit 2a according to the present embodiment, the third capacitance circuit 30a may have the variable capacitance circuit in which the two variable capacitive elements (variable capacitive elements VC31 and VC32) are connected in series to each other between the first terminal 31 and the second terminal 32, and the third terminal 33 may be a connection point where the two variable capacitive elements (variable capacitive elements VC31 and VC32) are connected to each other. The configuration of the third capacitance circuit 30a in the present embodiment is the same as that of the third capacitance circuit 30a in the phase shift circuit la according to the second embodiment.

The phase shift circuit 2a according to the present embodiment can readily change the capacitance connected in parallel to the inductance circuit 60, as the phase shift circuit la according to the second embodiment can. The phase shift circuit 2a achieved in the present embodiment therefore allows the amount of phase shift to be readily changed.

As shown in FIG. 4, in the phase shift circuit 2a according to the present embodiment, the first capacitance circuit 10, the second capacitance circuit 20, the fourth capacitance circuit 40, and the fifth capacitance circuit 50 may have the variable capacitive elements (variable capacitive element VC1, variable capacitive element VC2, variable capacitive element VC4, and variable capacitive element VC5), and the first voltage V1 may be applied in the form of a DC voltage to the first terminal 11 of the first capacitance circuit 10, the first terminal 21 of the second capacitance circuit 20, and the first terminal 31 of the third capacitance circuit 30a, the second voltage V2 may be applied in the form of a DC voltage to the second terminal 12 of the first capacitance circuit 10, the third voltage V3 may be applied in the form of a DC voltage to the second terminal 22 of the second capacitance circuit 20, the fourth voltage V4 may be applied in the form of a DC voltage to the third terminal 33 of the third capacitance circuit 30a, the fifth voltage V5 may be applied in the form of a DC voltage to the first terminal 41 of the fourth capacitance circuit 40, the first terminal 51 of the fifth capacitance circuit 50, and the second terminal 32 of the third capacitance circuit 30a, the sixth voltage V6 may be applied in the form of a DC voltage to the second terminal 42 of the fourth capacitance circuit 40, and the seventh voltage V7 may be applied in the form of a DC voltage to the second terminal 52 of the fifth capacitance circuit 50.

As a result, the capacitance of each of the first capacitance circuit 10, the second capacitance circuit 20, the third capacitance circuit 30a, the fourth capacitance circuit 40, and the fifth capacitance circuit 50 can be readily changed. The phase shift circuit 2a achieved in the present embodiment therefore allows the amount of phase shift to be readily changed.

In the phase shift circuit 2a according to the present embodiment, the second voltage V2, the third voltage V3, the fourth voltage V4, the sixth voltage V6, and the seventh voltage V7 may be the same voltage. In this case, a single control signal (voltage signal) can be used to readily change the capacitance of each of the first capacitance circuit 10, the second capacitance circuit 20, the third capacitance circuit 30a, the fourth capacitance circuit 40, and the fifth capacitance circuit 50.

Further, the phase shift circuit 2a according to the present embodiment provides the same advantageous effect as that provided by the phase shift circuit 1 according to the first embodiment, the phase shift circuit la according to the second embodiment, and the phase shift circuit 2 according to the third embodiment from the same reason.

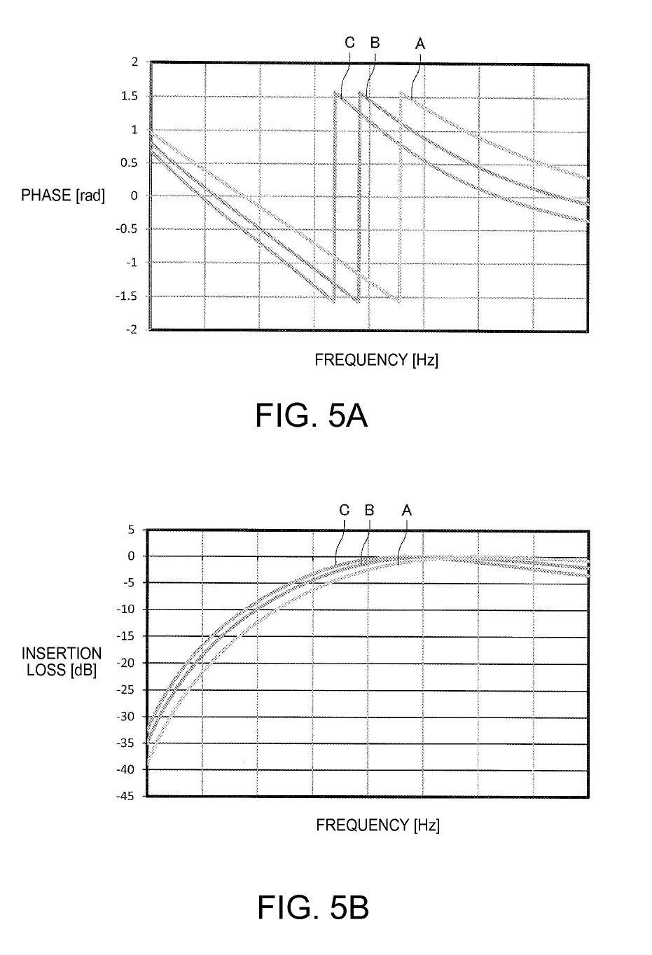

FIG. 5A shows graphs representing simulation results showing the relationship between the frequency and the phase associated with the phase shift circuit 2a. FIG. 5B shows graphs representing simulation results showing the relationship between the frequency and insertion loss associated with the phase shift circuit 2a. In FIG. 5A, the horizontal axis represents the frequency [Hz] of an input signal, and the vertical axis represents the difference in phase [rad] between the input signal and an output signal. In FIG. 5B, the horizontal axis represents the frequency [Hz] of the input signal, and the vertical axis represents gain [dB].

In the present simulation, it was assumed that the second voltage V2, the third voltage V3, the fourth voltage V4, the sixth voltage V6, and the seventh voltage V7 are the same voltage applied to the respective terminals, and the same applied voltage was changed by three steps. In FIGS. 5A and 5B, simulation results are labeled with A, B, and C in descending order of the applied voltage or in the order of A>B>C. It was further assumed that the first voltage V1 and the fifth voltage V5 are fixed.

In the present simulation, each of the variable capacitive elements (variable capacitive element VC1, variable capacitive element VC2, variable capacitive element VC4, variable capacitive element VC5, variable capacitive element VC31, and variable capacitive element VC32) shows smaller capacitance at a greater voltage across the variable capacitive element.

As shown in FIG. 5A, as the applied voltage increases (capacitance of variable capacitive element decreases), the phase of the output signal advances. As shown in FIG. 5B, as the applied voltage increases (capacitance of variable capacitive element decreases), the frequency at which the insertion loss is minimized increases.

As described above, in the phase shift circuit 2a according to the present embodiment, it is ascertained that the amount of phase shift can be controlled by using an external signal. The amount of phase shift can be similarly controlled based on the same principle in the phase shift circuit 1, the phase shift circuit la, and the phase shift circuit 2.

### 2. Oscillator

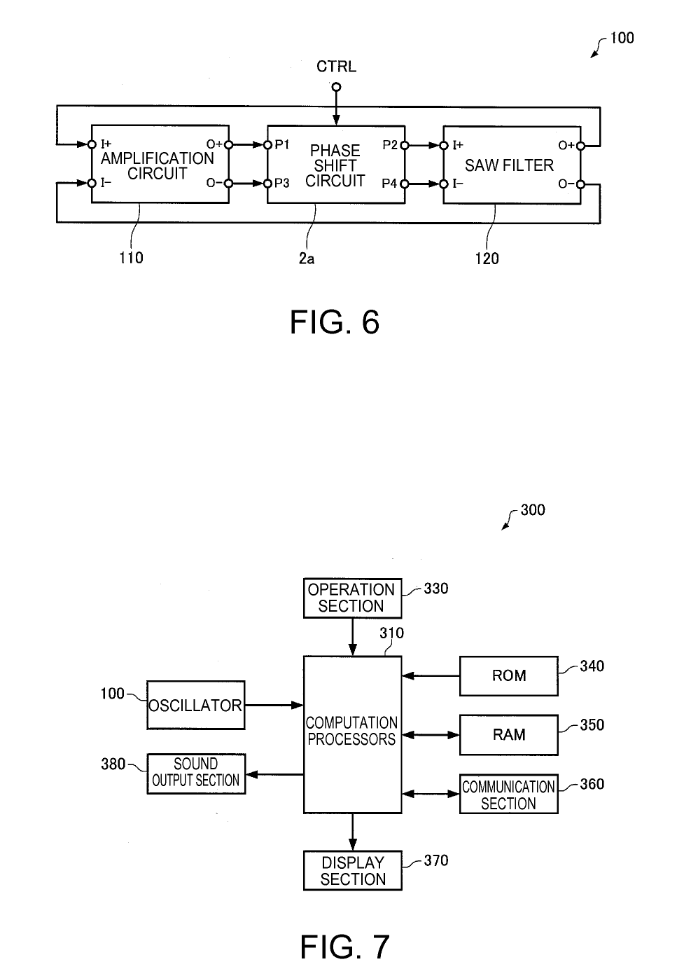

FIG. 6 is a circuit diagram of an oscillator 100 using the phase shift circuit 2a.

The oscillator 100 according to the present embodiment includes the phase shift circuit 2a, an amplification circuit 110, and an SAW filter 120.

The amplification circuit 110 is an amplification circuit having a differential output and a differential input. The amplification circuit 110 has a non-inversion input terminal I+, an inversion input terminal I−, a positive output terminal O+, and a negative output terminal O−. An output signal from the positive output terminal O+ is inputted to the terminal P1 of the phase shift circuit 2a. An output signal from the negative output terminal O− is inputted to the terminal P3 of the phase shift circuit 2a.

The SAW filter 120 is a bandpass filter that receives inputs through two terminals and sends outputs through two terminals. The SAW filter 120 has a non-inversion input terminal I+, an inversion input terminal I−, a positive output terminal O+, and a negative output terminal O−. An output signal from the positive output terminal O+ is inputted to the non-inversion input terminal I+ of the amplification circuit 110. An output signal from the negative output terminal O− is inputted to the inversion input terminal I− of the amplification circuit 110.

The phase shift circuit 2a has a control terminal CTRL. In the present embodiment, as the second voltage V2, the third voltage V3, the fourth voltage V4, the sixth voltage V6, and the seventh voltage V7, the same control signal is inputted through the control terminal CTRL.

The oscillator 100 shown in FIG. 6 performs oscillation when an oscillation condition is satisfied at a frequency where the total of delay in the phase produced by each of the amplification circuit 110, the phase shift circuit 2a, and the SAW filter 120 is an integer multiple of 360 degrees. When the control signal inputted through the control terminal CTRL changes the amount of phase shift in the phase shift circuit 2a, the frequency at which the oscillation condition is satisfied is changed. The oscillator 100 therefore functions as an oscillator capable of controlling the oscillation frequency in accordance with the control signal (voltage signal) inputted through the control terminal CTRL (VCO: voltage-controlled oscillator).

The oscillator 100 according to the present embodiment, which includes the phase shift circuit 2a, which allows the amount of phase shift to be readily changed, allows the oscillation frequency to be readily adjusted and controlled.

A configuration in which the phase shift circuit 2a is replaced with the phase shift circuit 1, the phase shift circuit la, or the phase shift circuit 2 can form the oscillator based on the same principle.

Further, in the above example, the description has been made of the case where the SAW filter 120 is used, but the SAW filter 120 is not necessarily used and can be replaced with the following components in accordance with purposes: a two-port resonator using a piezoelectric substrate made, for example, of quartz crystal, lithium tantalite (LiTaO₃), or a piezoelectric ceramic (such as quartz crystal oscillator, ceramic oscillator, and SAW resonator), a two-port filter using the piezoelectric substrate (such as quartz crystal filter, ceramic filter, and SAW filter), and other similar two-port components in general; and a two-port resonator, for example, using MEMS (micro electro mechanical systems) (such as MEMS oscillator), a two-port filter, for example, using MEMS (such as MEMS filter), and other similar two-port components in general. Examples of the two-port resonator and the two-port filter may include a longitudinally or laterally coupled SAW resonator (SAW filter), a transversal SAW filter, a monolithic quartz crystal filter, and a monolithic piezoelectric filter.

### 3. Electronic Apparatus

FIG. 7 is a functional block diagram of an electronic apparatus 300 according to the present embodiment. The same configurations as those in the embodiments described above have the same reference characters and will not be described in detail.

The electronic apparatus 300 according to the present embodiment includes the phase shift circuit 1, the phase shift circuit la, the phase shift circuit 2, or the phase shift circuit 2a. In the example shown in FIG. 7, the electronic apparatus 300 includes the oscillator 100 including the phase shift circuit 2a, a computation processor 310, an operation section 330, a ROM (read only memory) 340, a RAM (random access memory) 350, a communication section 360, a display section 370, and a sound output section 380. The electronic apparatus 300 according to the present embodiment may have a configuration in which part of the constituent elements (components) shown in FIG. 7 is omitted or changed or a configuration in which another constituent element is added.

The computation processor 310 performs a variety of types of calculation and control in accordance with a program stored, for example, in the ROM 340. Specifically, the computation processor 310 responds to an output signal from the oscillator 100 as a clock signal and performs a variety of processes according to an operation signal from the operation section 330, such as a process of controlling the communication section 360 for data communication with an external apparatus, a process of transmitting a display signal for display of a variety of types of information on the display section 370, and a process of causing the sound output section 380 to output a variety of sounds.

The operation section 330 is an input device formed, for example, of operation keys and button switches and outputs an operation signal according to user's operation to the computation processor 310.

The ROM 340 stores programs, data, and other types of information that allow the computation processor 310 to perform the variety of types of calculation and control.

The RAM 350 is used as a work area used by the computation processor 310 and temporarily stores a program and data read from the ROM 340, data inputted through the operation section 330, results of computation performed by the computation processor 310 in accordance with a variety of programs, and other types of information.

The communication section 360 performs a variety of types of control for establishing data communication between the computation processor 310 and an external apparatus.

The display section 370 is a display device formed, for example, of an LCD (liquid crystal display) and an electrophoresis display and displays a variety of types of information based on a display signal inputted from the computation processor 310.

The sound output section 380 is a device that outputs sounds, such as a loudspeaker.

The electronic apparatus 300 according to the present embodiment, which includes the phase shift circuit 2a, which allows the amount of phase shift to be readily changed, can readily change its operation. The electronic apparatus 300 including the phase shift circuit 1, the phase shift circuit la, or the phase shift circuit 2 in place of the phase shift circuit 2a provides the same advantageous effect.

The electronic apparatus 300 is conceivably any of a variety of electronic apparatus. Examples of the electronic apparatus 300 may include a personal computer (mobile personal computer, laptop personal computer, and tablet personal computer, for example), a portable phone, such as a mobile terminal, a digital still camera, an inkjet-type liquid ejection apparatus (inkjet printer, for example), a storage area network apparatus, such as a router and a switch, a local area network apparatus, a mobile terminal base station apparatus, a television receiver, a video camcorder, a video recorder, a car navigation system, a pager, an electronic notebook (including one with communication function), an electronic dictionary, a desktop calculator, an electronic game console, a game controller, a word processor, a workstation, a TV phone, a security television monitor, electronic binoculars, a POS (point of sales) terminal, a medical apparatus (such as electronic thermometer, blood pressure gauge, blood sugar meter, electrocardiograph, ultrasonic diagnostic apparatus, and electronic endoscope), a fish finder, a variety of measuring apparatus, a variety of instruments (such as instruments in vehicles, air planes, and ships), a flight simulator, a head-mounted display, a motion tracer, a motion tracker, and a motion controller, a PDR (pedestrian dead reckoning).

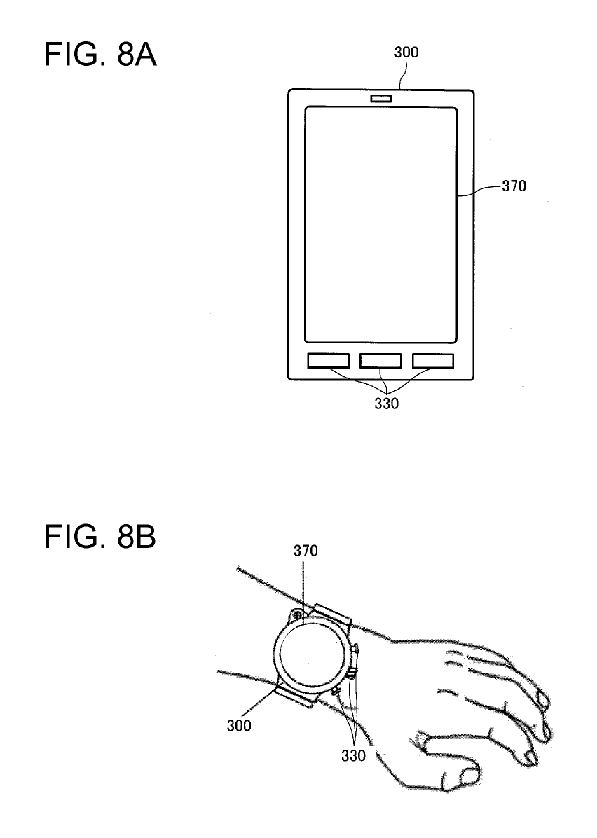

FIG. 8A shows an example of the exterior appearance of a smartphone, which is an example of the electronic apparatus 300, and FIG. 8B shows a wristwatch-type mobile apparatus as an example of the electronic apparatus 300. The smartphone shown in FIG. 8A as the electronic apparatus 300 includes buttons as the operation section 330 and an LCD as the display section 370. The wristwatch-type mobile apparatus shown in FIG. 8B as the electronic apparatus 300 includes buttons and a winding knob as the operation section 330 and an LCD as the display section 370. The electronic apparatus 300 described above, each of which includes the phase shift circuit 1, the phase shift circuit la, the phase shift circuit 2, or the phase shift circuit 2a, which allows the amount of phase shift to be readily changed, can readily change their operation.

### 4. Moving Object

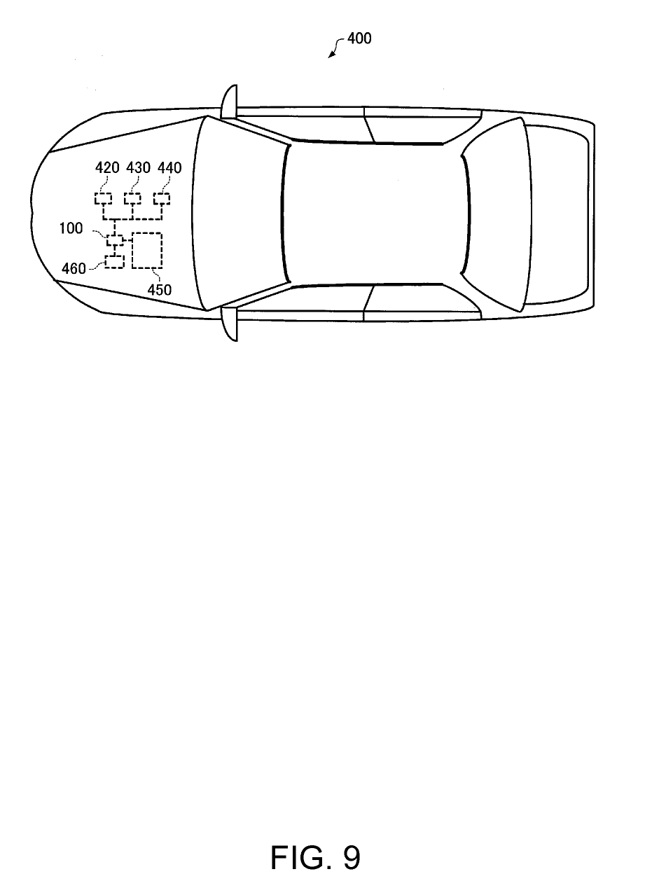

FIG. 9 shows an example of a moving object 400 according to the present embodiment (top view). The same configurations as those in the embodiments described above have the same reference characters and will not be described in detail.

The moving object 400 according to the present embodiment includes the phase shift circuit 1, the phase shift circuit la, the phase shift circuit 2, or the phase shift circuit 2a. The moving object 400 shown in FIG. 9 includes the oscillator 100 including the phase shift circuit 2a. In the example shown in FIG. 9, the moving object 400 includes a controller 420, a controller 430, and a controller 440, which perform a variety of types of control on an engine system, a brake system, a keyless entry system, and other systems, as well as a battery 450, and a backup battery 460. The moving object 400 according to the present embodiment may have a configuration in which part of the constituent elements (components) shown in FIG. 9 is omitted or changed or a configuration in which another constituent element is added.

The moving object 400 according to the present embodiment, which includes the phase shift circuit 2a, which allows the amount of phase shift to be readily changed, can readily change its operation. The moving object 400 including the phase shift circuit 1, the phase shift circuit la, or the phase shift circuit 2 in place of the phase shift circuit 2a provides the same advantageous effect.

The moving object 400 is conceivably any of a variety of moving objects, for example, an automobile (including electric automobile), an airplane, such as a jet plane and a helicopter, a ship, a rocket, and an artificial satellite.

The present embodiment or variations thereof have been described above, but the invention is not limited to the present embodiment or the variations thereof and can be implemented in a variety of other aspects to the extent that they do not depart from the substance of the invention.

The invention encompasses substantially the same configurations as the configurations described in the embodiments (for example, a configuration having the same function, using the same method, and providing the same result or a configuration having the same purpose and providing the same effect). Further, the invention encompasses a configuration in which an inessential portion of the configuration described in each of the embodiments is replaced. Moreover, the invention encompasses a configuration that provides the same advantageous effect as that provided in the configurations described in the embodiments or a configuration that can achieve the same purpose as that achieved by the configurations described in the embodiments. Further, the invention encompasses a configuration in which a known technology is added to the configuration described in any of the embodiments.

The entire disclosure of Japanese Patent Application No. 2014-075372, filed Apr. 1, 2014 is expressly incorporated by reference herein.

What is claimed is:

1. A phase shift circuit comprising:
a first capacitance circuit;
a second capacitance circuit;
an inductance circuit; and
a third capacitance circuit having a first terminal electrically connected to one end of the inductance circuit, a second terminal electrically connected to the other end of the inductance circuit, and a third terminal to which a signal that controls capacitance is inputted,
wherein one end of the first capacitance circuit, one end of the second capacitance circuit, the first terminal of the third capacitance circuit, and the one end of the inductance circuit are electrically connected to one another.

2. The phase shift circuit according to claim 1,
wherein the third capacitance circuit includes a switch element having the third terminal and a capacitive element, and
the switch element and the capacitive element are connected in series to each other between the first terminal and the second terminal.

3. The phase shift circuit according to claim 1,
wherein at least one of the first capacitance circuit, the second capacitance circuit, and the third capacitance circuit has a variable capacitive element.

4. The phase shift circuit according to claim 2,
wherein at least one of the first capacitance circuit, the second capacitance circuit, and the third capacitance circuit has a variable capacitive element.

5. The phase shift circuit according to claim 1,
wherein the third capacitance circuit has a variable capacitance circuit in which two variable capacitive elements are connected in series to each other between the first terminal and the second terminal, and
the third terminal is a connection point where the two variable capacitive elements are connected to each other.

6. The phase shift circuit according to claim 5,
wherein each of the first capacitance circuit and the second capacitance circuit has a variable capacitive element,
a first voltage is applied to the one end of the first capacitance circuit, the one end of the second capacitance circuit, and the first terminal of the third capacitance circuit,
a second voltage is applied in the form of a DC voltage to the other end of the first capacitance circuit,
a third voltage is applied in the form of a DC voltage to the other end of the second capacitance circuit, and
a fourth voltage is applied in the form of a DC voltage to the third terminal of the third capacitance circuit.

7. The phase shift circuit according to claim 6,
wherein the second voltage, the third voltage, and the fourth voltage are the same voltage.

8. The phase shift circuit according to claim 1, further comprising:
a fourth capacitance circuit; and
a fifth capacitance circuit,
wherein one end of the fourth capacitance circuit, one end of the fifth capacitance circuit, the second terminal of the third capacitance circuit, and the other end of the inductance circuit are electrically connected to one another.

9. The phase shift circuit according to claim 8,
wherein the third capacitance circuit includes a switch element having the third terminal and a capacitive element, and
the switch element and the capacitive element are connected in series to each other between the first terminal and the second terminal.

10. The phase shift circuit according to claim 8,
wherein at least one of the first capacitance circuit, the second capacitance circuit, the third capacitance circuit, the fourth capacitance circuit, and the fifth capacitance circuit has a variable capacitive element.

11. The phase shift circuit according to claim 9,
wherein at least one of the first capacitance circuit, the second capacitance circuit, the third capacitance circuit, the fourth capacitance circuit, and the fifth capacitance circuit has a variable capacitive element.

12. The phase shift circuit according to claim 8,
wherein the third capacitance circuit has a variable capacitance circuit in which two variable capacitive elements are connected in series to each other between the first terminal and the second terminal, and
the third terminal is a connection point where the two variable capacitive elements are connected to each other.

13. The phase shift circuit according to claim 12,
wherein each of the first capacitance circuit, the second capacitance circuit, the fourth capacitance circuit, and the fifth capacitance circuit has a variable capacitive element,
a first voltage is applied in the form of a DC voltage to the one end of the first capacitance circuit, the one end of the second capacitance circuit, and the first terminal of the third capacitance circuit,
a second voltage is applied in the form of a DC voltage to the other end of the first capacitance circuit,
a third voltage is applied in the form of a DC voltage to the other end of the second capacitance circuit,
a fourth voltage is applied in the form of a DC voltage to the third terminal of the third capacitance circuit,
a fifth voltage is applied in the form of a DC voltage to the one end of the fourth capacitance circuit, the one end of the fifth capacitance circuit, and the second terminal of the third capacitance circuit,
a sixth voltage is applied in the form of a DC voltage to the other end of the fourth capacitance circuit, and
a seventh voltage is applied in the form of a DC voltage to the other end of the fifth capacitance circuit.

14. The phase shift circuit according to claim 13,
wherein the second voltage, the third voltage, the fourth voltage, the sixth voltage, and the seventh voltage are the same voltage.

15. An oscillator comprising the phase shift circuit according to claim 1.

16. An oscillator comprising the phase shift circuit according to claim 2.

17. An electronic apparatus comprising the phase shift circuit according to claim 1.

18. An electronic apparatus comprising the phase shift circuit according to claim 2.

19. A moving object comprising the phase shift circuit according to claim 1.

20. A moving object comprising the phase shift circuit according to claim 2.
